(19) United States
(12) Patent Application Publication
(10) Pub. No.: US 2018/0097194 A1
(43) Pub. Date: Apr. 5, 2018

(54) LIGHT-EMITTING DEVICE, BACKLIGHT MODULE, AND DISPLAY DEVICE

(71) Applicant: Shenzhen China Star Optoelectronics Technology Co., Ltd., Shenzhen, Guangdong (CN)

(72) Inventor: Kaifeng ZHOU, Shenzhen, Guangdong (CN)

(73) Assignee: Shenzhen China Star Optoelectronics Technology Co., Ltd., Shenzhen, Guangdong (CN)

(21) Appl. No.: 15/039,425

(22) PCT Filed: Mar. 31, 2016
(86) PCT No.: PCT/CN2016/077948

§ 371 Date: May 26, 2016

(30) Foreign Application Priority Data
Mar. 15, 2016 (CN) 201610147109.7

(51) Int. Cl. H01L 51/50; H01L 51/52

(52) U.S. Cl. CPC H01L 51/5012; H01L 51/5056; H01L 51/52; H01L 51/5072; H01L 51/5092

(57) ABSTRACT

Disclosed is a light-emitting device including a base plate, an orientation layer, a photoluminescence layer, and an electroluminescence assembly. The orientation layer is arranged on the base plate. The photoluminescence layer and the orientation layer are adjacent to and stacked on one another. The orientation layer provides an effect of orientating to the photoluminescence layer. The electroluminescence assembly is arranged on one side of the photoluminescence layer that is distant from the orientation layer or on one side of the base plate that is distant from the orientation layer. The electroluminescence assembly includes a transparent anode, an electroluminescence layer, and a cathode sequentially stacked on each other and the transparent anode faces toward the base plate. Also disclosed are a backlight module including the light-emitting device and a display device including the backlight module.

### CROSS REFERENCE TO RELATED APPLICATIONS

This application claims the priority of Chinese Patent Application No. 201610147109.7, entitled “Light-Emitting Device, Backlight Module, and Display Device”, filed on Mar. 15, 2016, the disclosure of which is incorporated herein by reference in its entirety.

### BACKGROUND OF THE INVENTION

### 1. Field of the Invention

The present invention relates to the field of lighting sources, and in particular to a light-emitting device, a backlight module comprising the light-emitting device, and a display device comprising the backlight module.

### 2. The Related Arts

Light-emitting devices that are commonly known include electroluminescence light-emitting devices and photoluminescence light-emitting devices. The electroluminescence light-emitting devices possess various advantages, such as active luminescence, low power consumption, and light weight, and are thus widely used in all fields. The electroluminescence light-emitting devices are a kind of electronic devices that convert electrical power into optical power. A typical structure of the electroluminescence light-emitting devices is generally such that a transparent anode, an electroluminescence layer (such as an electroluminescent film), and a cathode sequentially formed on a transparent base plate. With the progress of the electroluminescent technology, polarized electroluminescence light-emitting devices are gradually gaining the attention of manufacturers. The polarized electroluminescence light-emitting devices, as a newly emerging direction of research and study, are widely used as backlighting sources of liquid crystal displays. The polarized electroluminescence light-emitting devices may directly emit polarized light so that the liquid crystal displays may save on polarizer thereby greatly improving the utilization of optical energy and simplifying internal component structure of the liquid crystal displays.

The polarized electroluminescence light-emitting devices additionally include an orientation layer on the basis of regular electroluminescence light-emitting devices. The polarized electroluminescence light-emitting devices rely on the orientation layer to achieve orientation of the electroluminescence layer in order to provide optic anisotropy and electrical anisotropy of the electroluminescence layer for achieving emission of polarized light.

However, since the polarized electroluminescence light-emitting devices must include an orientation layer to define the orientation of the electroluminescence layer, the material of the orientation layer has relatively great influence on the electroluminescence light-emitting devices. The orientation layer often has a relatively low capacity of carrier transportation (and is generally an insulation material), so that the light emission efficiency of the polarized electroluminescence devices is relatively low. Further, during a process of defining the orientation of the material of the orientation layer, such as rubbing orientation, surface defects may easily generated on the electroluminescence layer, readily causing luminescence quenching, thereby leading to low light emission efficiency of the polarized electroluminescence light-emitting devices.

### SUMMARY OF THE INVENTION

The technical issue that the present invention intends to resolve is to provide a light-emitting device, wherein the light-emitting device eliminates the drawbacks of low carrier transportation capacity and surface defects present on an electroluminescence layer caused by an orientation layer thereby helping improve light emission efficiency of the light-emitting device.

To resolve the above problem, the present invention the following technical solution:

In a first aspect, the present invention provides a light-emitting device. The light-emitting device comprises a base plate, an orientation layer, a photoluminescence layer, and an electroluminescence assembly. The orientation layer is arranged on the base plate. The photoluminescence layer and the orientation layer re adjacent to and stacked on each other. The orientation layer provides an effect of orientating to the photoluminescence layer. The electroluminescence assembly is arranged on one side of the photoluminescence layer that is distant from the orientation layer or on one side of the base plate that is distant from the orientation layer. The electroluminescence assembly comprises a transparent anode, a electroluminescence layer, and a cathode that are sequentially stacked and the transparent anode faces toward the base plate.

In the above light-emitting device, the photoluminescence layer is formed of a material having optical anisotropy and electrical anisotropy.

In the above light-emitting device, the photoluminescence layer is formed of a material comprising at least one of a red light emission material, a green light emission material, a blue light emission material, and a yellow light emission material.

In the above light-emitting device, the photoluminescence layer comprises poly(2-(4-(3′,7′-dimethyloctyloxyphenyl)-1,4-phenylene vinylene) and/or poly(2-methoxy, 5-(2′-ethylhexyloxy)-1,4-phenylene vinylene).

In the above light-emitting device, the electroluminescence layer is formed of a material comprising at least one of a blue light emission material, a red light emission material, and an ultraviolet light emission material.

In the above light-emitting device, the electroluminescence layer comprises poly(9,9-dioctylfluorene-2,7-diyl).

In the above light-emitting device, the electroluminescence assembly further comprises a hole transportation layer and an electron transportation layer. The hole transportation layer is arranged between the electroluminescence layer and the transparent anode. The electron transportation layer is arranged between the electroluminescence layer and the cathode.

In the above light-emitting device, the electroluminescence assembly further comprises a hole injection layer and an electron injection layer. The hole injection layer is arranged between the hole transportation layer and the transparent anode. The electron injection layer is arranged between the electron transportation layer and the cathode.

In a second aspect, the present invention provides a backlight module, and the backlight module comprises the light-emitting device described above.

In a third aspect, the present invention provides a display device, and the display device comprises the backlight module described above.

Compared to the prior art, the present invention provides at least the following advantages:

In the technical solution of the present invention, the light-emitting device comprises a base plate, an electroluminescence assembly, a photoluminescence layer, and an orientation layer. The orientation layer is arranged on the base plate. The photoluminescence layer and the orientation layer are adjacent to and stacked on each other. The orientation layer provides an effect of orientating to the photoluminescence layer. The electroluminescence assembly is arranged on one side of the photoluminescence layer that is distant from the orientation layer or on one side of the base plate that is distant from the orientation layer. The electroluminescence assembly comprises a transparent anode, a electroluminescence layer, and a cathode that are sequentially stacked and the transparent anode faces toward the base plate.

In other words, the orientation layer is not arranged in the electroluminescence assembly and is instead formed on the base plate and adjacent to the photoluminescence layer to provide an effect of orientating to the photoluminescence layer. Since the photoluminescence layer does not need to transport charge carriers, the orientation layer does not impose any negative influence on the photoluminescence layer, thereby preventing the orientation layer from lowering the carrier transportation capability of the electroluminescence assembly. Further, since the orientation layer is arranged on the base plate, surface defects caused in the electroluminescence layer during orienting of the orientation layer can be avoided, thereby improving overall light emission efficiency of the light-emitting device.

### BRIEF DESCRIPTION OF THE DRAWINGS

To more clearly explain the technical solution proposed in an embodiment of the present invention and that of the prior art, brief descriptions of the drawings that are necessary for describing the embodiment or the prior art are given as follows. It is obvious that the drawings that will be described below show only some embodiments of the present invention. For those having ordinary skills of the art, other drawings may also be readily available from these attached drawings without the expense of creative effort and endeavor.

FIG. 1 is a schematic view showing a light-emitting device according to a first embodiment of the present invention;

FIG. 2 is a schematic view illustrating an example of the light-emitting device according to the first embodiment of the present invention;

FIG. 3 is a schematic view showing a light-emitting device according to a second embodiment of the present invention; and

FIG. 4 is a schematic view showing a light-emitting device according to a third embodiment of the present invention.

### DETAILED DESCRIPTION OF THE PREFERRED EMBODIMENTS

A clear and complete description will be given to technical solutions of embodiments of the present invention with reference to the attached drawings of the embodiments of the present invention. However, the embodiments so described are only some, but not all, of the embodiments of the present invention. Other embodiments that are available to those having ordinary skills of the art without the expense of creative effort and endeavor are considered belonging to the scope of protection of the present invention.

Further, the following descriptions of the various embodiments are made with reference to the attached drawings for illustrating, in an exemplary way, specific embodiments to which the present invention is applicable. Directional terminology, such as “up”, “down”, “front”, “rear”, “left”, “right”, “internal”, “external”, and “side”, used in the present invention are described according to the direction shown in the drawings and are not intended to indicate or suggest a designated device or element must be of a specific direction or be constructed or operated in a specific direction and thus they should not be construed as constraint to the scope of the present invention.

In the description of the present invention, it is noted that unless explicitly specified or constrained, the terms “mounting”, “interconnecting”, and “connecting” should be interpreted as fixed connection and may alternatively be releasable connection or integral connection; or being mechanically connected; or in direction connection with each other or interconnected through an intermediate medium; or being communication between interiors of two elements. For those having ordinary skills in the art can appreciate the meaning of these terms as used in the present invention in specific conditions.

Further, unless specified otherwise, in the description of the present invention, “plural” means two or more than two. The term “operation”, when appearing in the specification, does not just include an independent operation and may also include a desired effect of the operation achieved with the operation when the operation is not distinguishable from other operations. The symbol “-” used in the present invention to define a numeric range, of which the minimum and maximum are respectively corresponding to the figures set in front of and behind of the symbol “-”. In the attached drawings, similar structures or identical units are designated with the same reference numerals.

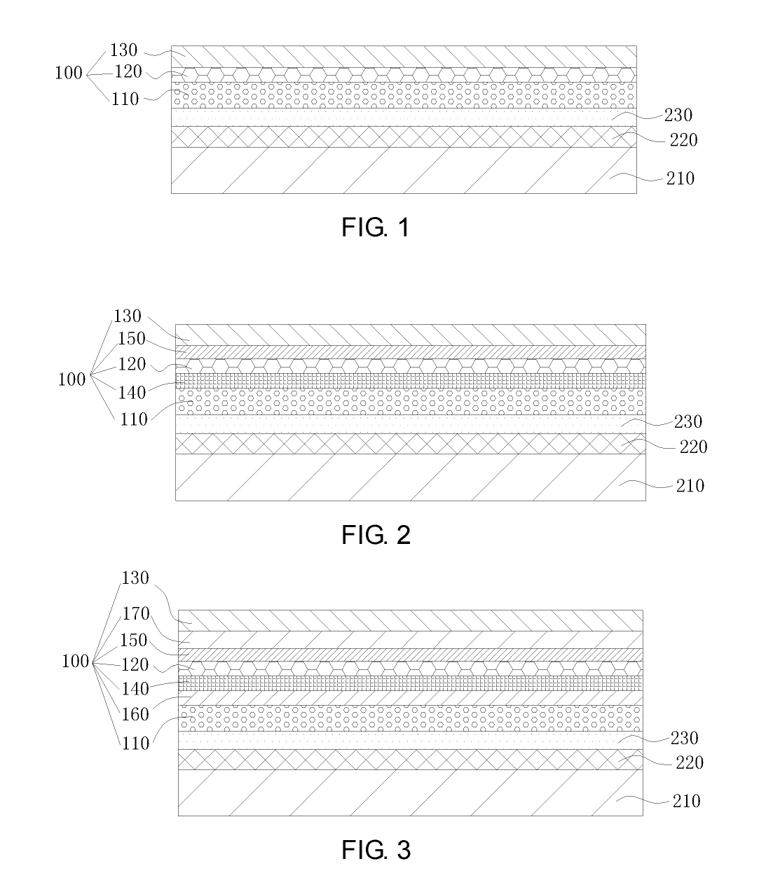

Referring to FIG. 1, FIG. 1 is a schematic view illustrating a light-emitting device according to a first embodiment of the present invention. In the first embodiment of the present invention, the light-emitting device comprises a base plate 210, an orientation layer 220, a photoluminescence layer 330, and an electroluminescence assembly 100. The orientation layer 220 is arranged on the base plate 210. The photoluminescence layer 230 is adjacent to and stacked on the orientation layer 230, namely the photoluminescence layer 220 is arranged on the orientation layer 220. The orientation layer 220 provides an effect of orientating to the photoluminescence layer 230. The electroluminescence assembly 100 is arranged on one side the photoluminescence layer 230 that is distant from the orientation layer 220. The electroluminescence assembly comprises a transparent anode 110, an electroluminescence layer 120, and a cathode 130, which are sequentially stacked, and the transparent anode 110 faces toward the base plate 210.

The orientation layer 220 is formed of a material that comprises polyimide (PI) or polyvinylcarbazole (PVK). The orientation layer 220 can be oriented through rubbing orientation or optical orientation. The photoluminescence layer 230 may possess optical anisotropy and electrical anisotropy; in other words, the photoluminescence layer 230 is formed of a material of optical anisotropy and electrical anisotropy. The optical anisotropy of the photoluminescence layer 230 means light, when propagating in different directions in the photoluminescence layer, shows different optical properties; the electrical anisotropy of the photoluminescence layer 230 means the photoluminescence layer 230 shows differences of electrical property in different directions in the interior thereof. Thus, through the oriented orientation layer 220, orientating of the photoluminescence layer 230 can be achieved, allowing the light-emitting device to emit polarized light.

Specifically, the electroluminescence assembly 100 comprises the transparent anode 110, the electroluminescence layer 120, and the cathode 130 that are sequentially stacked on the photoluminescence layer. The transparent anode 110 is formed of a material comprising indium tin oxide, and the cathode 130 can be aluminum or magnesium.

The electroluminescence layer 120 can be formed of a material comprising at least one of a blue light emission material, a red light emission material, and an ultraviolet light emission material. Namely, the material of the electroluminescence layer 120 can be one of a blue light emission material, a red light emission material, and an ultraviolet light emission material, or a combination of two or more of a blue light emission material, a red light emission material, and an ultraviolet light emission material. For example, the electroluminescence layer 120 may comprise a blue light emission material, poly(9,9-dioctylfluorene-2,7-diyl) (PFO), and/or graphene oxide and reduced graphene oxide (GO and rGO). The electroluminescence layer 120 may have a thickness of 40-100 nm.

The photoluminescence layer 230 may comprise a material comprising one of a red light emission material, a green light emission material, a blue light emission material, and a yellow light emission material, or a combination of two or more of a red light emission material, a green light emission material, a blue light emission material, and a yellow light emission material. For example, the photoluminescence layer 230 may comprise a green light emission material, poly(2-(4-(3′,7′-dimethyloctyloxyphenyl)-1,4-phenylene vinylene) (P-PPV), and/or a red light emission material, poly(2-methoxy, 5-(2′-ethylhexyloxy)-1,4-phenylene vinylene) (EH-P-PPV). The photoluminescence layer 230 may have a thickness of 20-200 nm.

When a drive voltage is applied to the transparent anode 110 and the cathode 130, an electrical current is established to inject hole from the transparent anode 110 to the electroluminescence layer 120 and inject electrons from the cathode 130 to the electroluminescence layer 120 such that the holes and the electrons recombine in the electroluminescence layer 120 to emit light. A portion of light so emitted is reflected by the cathode 130 to transmit through the electroluminescence layer 120 and the transparent anode 110 to irradiate the photoluminescence layer 230, while a remaining portion transmits directly through the transparent anode 110 to irradiate the photoluminescence layer 230, such that the photoluminescence layer 230 is excited by the light from the electroluminescence assembly 100 to in turn emit light. Due to the orientation layer 230, eventually, polarized light is projected out. The polarized light so projected out carries a color that is determined by the material of the electroluminescence layer 120 and the material of the photoluminescence layer 230. For example, when the material of the electroluminescence layer 120 is the blue light emission material, PFO, while the material of the photoluminescence layer 230 is the red light emission material, EH-P-PPV, blue light emitting from the electroluminescence assembly 100 will be eventually converted by the photoluminescence layer 230 and the orientation layer 220 into while polarized light.

Further, referring to FIG. 2, FIG. 2 is a schematic view illustrating an example of the light-emitting device according to the first embodiment of the present invention. The electroluminescence assembly 100 may further comprise a hole transportation layer 140 and an electron transportation layer 150. The hole transportation layer 140 is arranged between the electroluminescence layer 120 and the transparent anode 110 and the electron transportation layer 150 is arranged between the electroluminescence layer 120 and the cathode 130. In this example, the hole transportation layer 140 helps increase the mobility of holes from the transparent anode 110 to the electroluminescence layer 120, and the electron transportation layer 150 helps increase the mobility of electrons from the cathode 130 to the electroluminescence layer 120, such that the electrons and the holes can be re-combine at a higher efficiency, making the light emission efficiency higher and energy consumption reduced.

In the instant embodiment (the first embodiment), the orientation layer is not arranged in the electroluminescence assembly and is instead formed on the base plate and adjacent to the photoluminescence layer to provide an effect of orientating to the photoluminescence layer. Since the photoluminescence layer does not need to transport charge carriers, the orientation layer does not impose any negative influence on the photoluminescence layer, thereby preventing the orientation layer from lowering the carrier transportation capability of the electroluminescence assembly. Further, since the orientation layer is arranged on the base plate, surface defects caused in the electroluminescence layer during orienting of the orientation layer can be avoided, thereby improving overall light emission efficiency of the light-emitting device.

Referring to FIG. 3, FIG. 3 is a schematic view illustrating a light-emitting device according to a second embodiment of the present invention. The light-emitting device of the instant embodiment (the second embodiment) has a structure that is generally identical to that of the light-emitting device of the first embodiment and a difference resides in that in the light-emitting device of the instant embodiment, the electroluminescence assembly 100 further comprises a hole injection layer 160 and an electron injection layer 170. The hole injection layer 160 is arranged between the hole transportation layer 140 and the transparent electrode 110, and the electron injection layer 170 is arranged between the electron transportation layer 150 and the cathode 130.

When a drive voltage is applied to the transparent anode 110 and the cathode 130, an electrical current flows through the transparent anode 110 such that the transparent anode 110 inject holes, at a high efficiency, through the hole injection layer 160 to the hole transportation layer 140 and the hole transportation layer 140 transports the holes to the electroluminescence layer 120 thereby increasing the mobility of the holes; meanwhile, the cathode 130 injects electrons, at a high efficiency, through the electron injection layer 170 to the electron transportation layer 150 and the electron transportation layer 150 in turn transports the electrons to the electroluminescence layer 120 thereby increasing the mobility of the electrons and consequently, the holes and the electrons re-combine in the electroluminescence layer 120 to emit light to thereby increasing light emission efficiency of the light-emitting device. A portion of the light emitting from the electroluminescence layer 120 is reflected the cathode 130 to transmit through the electron injection layer 170, the electron transportation layer 150, the electroluminescence layer 120, the hole transportation layer 140, the hole injection layer 160, and the transparent anode 110 to finally irradiate the photoluminescence layer 230, while a remaining portion transmits directly through the hole transportation layer 140, the hole injection layer 160, and the transparent anode 110 to irradiate the photoluminescence layer 230, such that the photoluminescence layer 230 is excited by the light from the electroluminescence layer 120 to emit light. Due to the orientation layer 230, eventually, polarized light is projected out from the light-emitting device. The polarized light so projected out carries a color that is determined by the material of the electroluminescence layer 120 and the material of the photoluminescence layer 230. For example, when the material of the electroluminescence layer 120 is the blue light emission material, PFO, while the material of the photoluminescence layer 230 is the red light emission material, EH-P-PPV, blue light emitting from the electroluminescence assembly 100 will be eventually converted by the photoluminescence layer 230 and the orientation layer 220 into white polarized light.

In the instant embodiment, due to the hole injection layer 160 arranged between the hole transportation layer 140 and the transparent electrode 110 and the electron injection layer 170 arranged between the electron transportation layer 150 and the cathode 130, the mobility of holes and electrons is greatly increased thereby increasing the light emission efficiency of the light-emitting device, lowering the drive voltage, and reducing energy consumption.

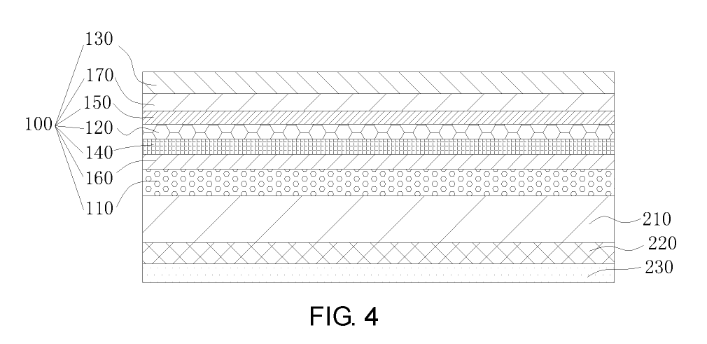

Referring to FIG. 4, FIG. 4 is a schematic view illustrating a light-emitting device according to a third embodiment of the present invention. The light-emitting device of the instant embodiment (the third embodiment) has a structure that is generally identical to that of the light-emitting device of the second embodiment and a difference resides in that in the light-emitting device of the instant embodiment, the photoluminescence layer 230 is arranged on one side of the base plate 210 that is distant from the orientation layer 220. In other words, the orientation layer 220 and the photoluminescence layer 230 are sequentially stacked on the side of the base plate 210 that is distant from the electroluminescence assembly 100.

In the instant embodiment, due to the orientation layer 220 and the photoluminescence layer 230 being sequentially stacked on the side of the base plate 210 that is distant from the electroluminescence assembly 10, the electroluminescence assembly 100 can be readily formed on the side of the base plate 210 that is not provided with the orientation layer 220 and the photoluminescence layer 230 and rubbing orientating applied to the orientation layer 220 does not cause damage to any function layer of the electroluminescence assembly 100 and, thus, the overall light emission efficiency of the light-emitting device can be increased.

A further embodiment of the present invention provides a backlight module, and the backlight module comprises the light-emitting device described above with reference to any one of the mentioned embodiments.

A further embodiment of the present invention provides a display device, and the display device comprises the backlight module described above.

In the description of the disclosure, the terms “an embodiment”, “some embodiments”, “example”, “specific examples”, or “some examples” are used to identify specific features, structures, materials, or characteristics described with the embodiment or example included in at least one embodiment or example of the present invention. In the disclosure, the use of the above terms does not mean the same embodiment or example. Further, the description of the specific features, structures, materials, or characteristics can be applied, in any suitable form, to one or multiple embodiments or examples.

The embodiments illustrated above are not construed as limiting the scope of protection of the technical solutions. Modifications, equivalent substitutions, and improvements that are made without departing from the spirits and principles of the above-described embodiments are considered within the scope of protection of the technical solutions.

What is claimed is:

1. A light-emitting device, comprising a base plate, an orientation layer, a photoluminescence layer, and an electroluminescence assembly, the orientation layer being arranged on the base plate, the photoluminescence layer and the orientation layer being adjacent to and stacked on each other, the orientation layer providing an effect of orientating to the photoluminescence layer, the electroluminescence assembly being arranged on one side of the photoluminescence layer that is distant from the orientation layer or on one side of the base plate that is distant from the orientation layer, the electroluminescence assembly comprising a transparent anode, a electroluminescence layer, and a cathode that are sequentially stacked such that the transparent anode faces toward the base plate.

2. The light-emitting device as claimed in claim 1, wherein the photoluminescence layer is formed of a material having optical anisotropy and electrical anisotropy.

3. The light-emitting device as claimed in claim 2, wherein the photoluminescence layer is formed of a material comprising at least one of a red light emission material, a green light emission material, a blue light emission material, and a yellow light emission material and the electroluminescence layer is formed of a material comprising at least one of a blue light emission material, a red light emission material, and an ultraviolet light emission material.

4. The light-emitting device as claimed in claim 3, wherein the photoluminescence layer comprises poly(2-(4-(3′,7′-dimethyloctyloxyphenyl)-1,4-phenylene vinylene) and/or poly(2-methoxy, 5-(2′-ethylhexyloxy)-1,4-phenylene vinylene), and the electroluminescence layer comprises poly(9,9-dioctylfluorene-2,7-diyl).

5. The light-emitting device as claimed in claim 1, wherein the electroluminescence assembly further comprises a hole transportation layer and an electron transportation layer, the hole transportation layer being arranged between the electroluminescence layer and the transparent anode, the electron transportation layer being arranged between the electroluminescence layer and the cathode.

6. The light-emitting device as claimed in claim 2, wherein the electroluminescence assembly further comprises a hole transportation layer and an electron transportation layer, the hole transportation layer being arranged between the electroluminescence layer and the transparent anode, the electron transportation layer being arranged between the electroluminescence layer and the cathode.

7. The light-emitting device as claimed in claim 3, wherein the electroluminescence assembly further comprises a hole transportation layer and an electron transportation layer, the hole transportation layer being arranged between the electroluminescence layer and the transparent anode, the electron transportation layer being arranged between the electroluminescence layer and the cathode.

8. The light-emitting device as claimed in claim 4, wherein the electroluminescence assembly further comprises a hole transportation layer and an electron transportation layer, the hole transportation layer being arranged between the electroluminescence layer and the transparent anode, the electron transportation layer being arranged between the electroluminescence layer and the cathode.

9. The light-emitting device as claimed in claim 5, wherein the electroluminescence assembly further comprises a hole injection layer and an electron injection layer, the hole injection layer being arranged between the hole transportation layer and the transparent anode, the electron injection layer being arranged between the electron transportation layer and the cathode.

10. The light-emitting device as claimed in claim 6, wherein the electroluminescence assembly further comprises a hole injection layer and an electron injection layer, the hole injection layer being arranged between the hole transportation layer and the transparent anode, the electron injection layer being arranged between the electron transportation layer and the cathode.

11. The light-emitting device as claimed in claim 7, wherein the electroluminescence assembly further comprises a hole injection layer and an electron injection layer, the hole injection layer being arranged between the hole transportation layer and the transparent anode, the electron injection layer being arranged between the electron transportation layer and the cathode.

12. The light-emitting device as claimed in claim 8, wherein the electroluminescence assembly further comprises a hole injection layer and an electron injection layer, the hole injection layer being arranged between the hole transportation layer and the transparent anode, the electron injection layer being arranged between the electron transportation layer and the cathode.

13. A backlight module, comprising a light-emitting device, the light-emitting device comprising a base plate, an orientation layer, a photoluminescence layer, and an electroluminescence assembly, the orientation layer being arranged on the base plate, the photoluminescence layer and the orientation layer being adjacent to and stacked on each other, the orientation layer providing an effect of orientating to the photoluminescence layer, the electroluminescence assembly being arranged on one side of the photoluminescence layer that is distant from the orientation layer or on one side of the base plate that is distant from the orientation layer, the electroluminescence assembly comprising a transparent anode, a electroluminescence layer, and a cathode that are sequentially stacked such that the transparent anode faces toward the base plate.

14. The backlight module as claimed in claim 13, wherein the photoluminescence layer is formed of a material having optical anisotropy and electrical anisotropy.

15. The backlight module as claimed in claim 14, wherein the photoluminescence layer is formed of a material comprising at least one of a red light emission material, a green light emission material, a blue light emission material, and a yellow light emission material and the electroluminescence layer is formed of a material comprising at least one of a blue light emission material, a red light emission material, and an ultraviolet light emission material.

16. The backlight module as claimed in claim 15, wherein the photoluminescence layer comprises poly(2-(4-(3′,7′-dimethyloctyloxyphenyl)-1,4-phenylene vinylene) and/or poly(2-methoxy, 5-(2′-ethylhexyloxy)-1,4-phenylene vinylene), and the electroluminescence layer comprises poly(9,9-dioctylfluorene-2,7-diyl).

17. The backlight module as claimed in claim 16, wherein the electroluminescence assembly further comprises a hole transportation layer and an electron transportation layer, the hole transportation layer being arranged between the electroluminescence layer and the transparent anode, the electron transportation layer being arranged between the electroluminescence layer and the cathode.

18. The backlight module as claimed in claim 17, wherein the electroluminescence assembly further comprises a hole injection layer and an electron injection layer, the hole injection layer being arranged between the hole transportation layer and the transparent anode, the electron injection layer being arranged between the electron transportation layer and the cathode.

19. A display device, comprising a backlight module, the backlight module comprising a light-emitting device, the light-emitting device comprising a base plate, an orientation layer, a photoluminescence layer, and an electroluminescence assembly, the orientation layer being arranged on the base plate, the photoluminescence layer and the orientation layer being adjacent to and stacked on each other, the orientation layer providing an effect of orientating to the photoluminescence layer, the electroluminescence assembly being arranged on one side of the photoluminescence layer that is distant from the orientation layer or on one side of the base plate that is distant from the orientation layer, the electroluminescence assembly comprising a transparent anode, a electroluminescence layer, and a cathode that are sequentially stacked such that the transparent anode faces toward the base plate.

20. The display device as claimed in claim 19, wherein the photoluminescence layer is formed of a material having optical anisotropy and electrical anisotropy; and the photoluminescence layer is formed of a material comprising at least one of a red light emission material, a green light emission material, a blue light emission material, and a yellow light emission material and the electroluminescence layer is formed of a material comprising at least one of a blue light emission material, a red light emission material, and an ultraviolet light emission material.
